(19) United States
(12) Patent Application Publication
(10) Pub. No.: US 2015/0053867 A1
(43) Pub. Date: Feb. 26, 2015

(54) PATTERN FORMATION METHOD, MASK FOR PATTERN FORMATION, METHOD FOR MANUFACTURING MASK, AND PATTERN FORMATION APPARATUS

(71) Applicant: KABUSHIKI KAISHA TOSHIBA, Tokyo (JP)

(72) Inventors: Ryoichi INANAMI, Kanagawa-ken (JP); Shinichi Ito, Kanagawa-Ken (JP); Takashi Sato, Kanagawa-ken (JP)

(73) Assignee: KABUSHIKI KAISHA TOSHIBA, Tokyo (JP)

(21) Appl. No.: 14/095,480

(22) Filed: Dec. 3, 2013

(30) Foreign Application Priority Data
Aug. 20, 2013 (JP) 2013-170793

(51) Int. Cl. H01J 37/317; H01J 37/22

(52) U.S. Cl. CPC H01J 37/3175; H01J 37/3177; H01J 37/22; H01J 2209/00
USPC 250/454.11; 250/492.3; 29/592.1; 29/887

(57) ABSTRACT

According to one embodiment, a pattern formation method includes: preparing a mask pattern for interference, a photoelectric conversion unit, and a processing object, the mask pattern for interference being periodically arranged a plurality of light transmissive portions, the photoelectric conversion unit being disposed apart from the mask pattern for interference; applying light to the mask pattern for interference to produce Talbot interference based on transmitted light of the light transmitted through the light transmissive portions; applying interference light produced by the Talbot interference to the photoelectric conversion unit to cause the photoelectric conversion unit to emit electrons based on the interference light; and forming a pattern by applying the electrons to the processing object.

### CROSS-REFERENCE TO RELATED APPLICATIONS

This application is based upon and claims the benefit of priority from Japanese Patent Application No. 2013-170793, filed on Aug. 20, 2013; the entire contents of which are incorporated herein by reference.

### FIELD

Embodiments described herein relate generally to a pattern formation method, a mask for pattern formation, a method for manufacturing a mask, and a patterm formaistion aparatus.

### BACKGROUND

In lithography using an electron beam, even a fine pattern can be formed with high accuracy by converging the electron beam. However, in the conventional electron beam exposure apparatus, it is necessary to move an electron beam in a manner of what is called single stroke drawing, and it is difficult to expose a large area in a short time.

As another lithography technology, there is an exposure method using Talbot interference. Talbot interference is a phenomenon in which when coherent light with good coherence is applied to a mask for exposure having a repeating pattern, a reversed image and a self-produced image of the pattern appear periodically in the direction of light traveling. When pattern transfer is performed by utilizing the reversed image or the self-produced image, the transfer of a pattern defect included in the mask for exposure is suppressed. In the pattern formation method using lithography technology, it is desirable to form a high accuracy pattern in a large area in a short time.

### BRIEF DESCRIPTION OF THE DRAWINGS

FIG. 1 is a flow chart illustrating a pattern formation method according to a first embodiment;

FIG. 2 is a schematic view illustrating a mask pattern for Talbot interference and aspect of Talbot interference;

FIG. 3A and FIG. 3B are schematic views illustrating a mask for pattern formation;

FIG. 4A to FIG. 4E are schematic cross-sectional views illustrating patterns of the photoelectric conversion unit;

FIG. 5 is a schematic view illustrating a pattern formation apparatus;

FIG. 6A to FIG. 6C are schematic views illustrating a pattern formation method according to the third embodiment;

FIG. 7A to FIG. 9D are schematic views illustrating methods for forming a pattern of electrons;

FIG. 10A to FIG. 10E are schematic views illustrating a pattern formation method according to the fourth embodiment;

FIG. 11A to FIG. 11C are schematic cross-sectional views illustrating masks for pattern formation; and

FIG. 12A to FIG. 17D are schematic cross-sectional views illustrating methods for manufacturing a mask for pattern formation.

### DETAILED DESCRIPTION

In general, according to one embodiment, a pattern formation method includes: preparing a mask pattern for interference, a photoelectric conversion unit, and a processing object, the mask pattern for interference being periodically arranged a plurality of light transmissive portions, the photoelectric conversion unit being disposed apart from the mask pattern for interference; applying light to the mask pattern for interference to produce Talbot interference based on transmitted light of the light transmitted through the light transmissive portions; applying interference light produced by the Talbot interference to the photoelectric conversion unit to cause the photoelectric conversion unit to emit electrons based on the interference light; and forming a pattern by applying the electrons to the processing object.

Various embodiments will be described hereinafter with reference to the accompanying drawings. In the following description, identical components are marked with the same reference numerals, and a description of components once described is omitted as appropriate.

### First Embodiment

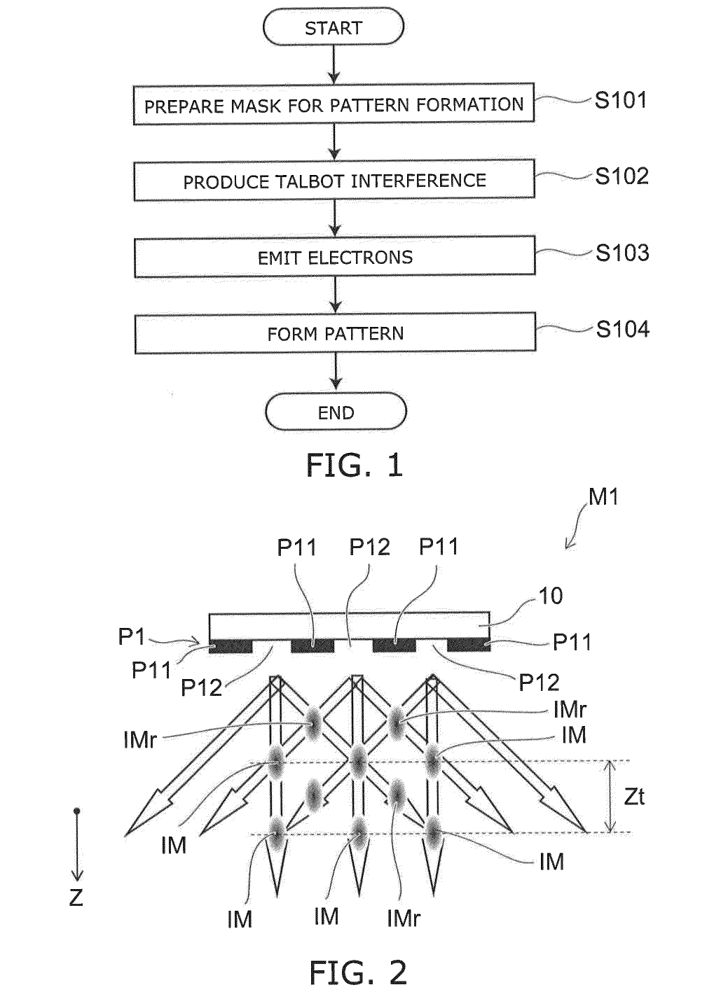

FIG. 1 is a flow chart illustrating a pattern formation method according to a first embodiment.

As shown in FIG. 1, the pattern formation method according to the embodiment includes the preparation of a mask for pattern formation (step S101), the production of Talbot interference (step S102), the emission of electrons (step S103), and the formation of a pattern (step S104).

In the preparation of a mask for pattern formation shown in step S101, a mask for pattern formation is prepared that includes a mask pattern for interference in which a plurality of light transmissive portions are arranged periodically and a photoelectric conversion unit disposed apart from the mask pattern for interference. Aspects of the mask for pattern formation are described later.

FIG. 2 is a schematic view illustrating a mask pattern for Talbot interference and aspect of Talbot interference.

FIG. 2 shows an example in which a mask pattern for interference P1 is provided in a mask for interference M1. As shown in FIG. 2, the mask for interference M1 includes a substrate 10 that transmits light of a prescribed wavelength and the mask pattern for interference P1 provided on the substrate 10. The mask pattern for interference P1 has a plurality of light blocking pattern features P11 and a plurality of light transmissive pattern features P12. The light blocking pattern feature P11 blocks the light mentioned above. The light transmissive pattern feature P12 transmits the light mentioned above.

Quartz or synthetic quartz is used for the substrate 10, for example. Chromium (Cr) is used for the light blocking pattern feature P11, for example.

The plurality of light blocking pattern features P11 are arranged on the substrate 10 with a prescribed width and a prescribed interval. The plurality of light transmissive pattern features P12 are each provided between light blocking pattern features P11. Thus, the plurality of light transmissive pattern features P12 are provided periodically on the substrate 10. The plurality of light blocking pattern features P11 and the plurality of light transmissive pattern features P12 constitute a line-and-space pattern, for example. The plurality of light blocking pattern features P11 and the plurality of light transmissive pattern features P12 may constitute an island-like pattern or more complicated shape.

In the production of Talbot interference shown in step S102, the light mentioned above is applied to the mask pattern for interference P1 to produce Talbot interference based on the transmitted light resulting from the light transmitted through the plurality of light transmissive pattern features P12.

FIG. 2 illustrates Talbot interference produced by the mask for interference M1. The Talbot interference is a phenomenon in which when coherent light with good coherence is applied to the repeating pattern of the mask pattern for interference P1 (the light blocking pattern features P11 and the light transmissive pattern features P12), a reversed image IMr and a self-produced image IM of the repeating pattern of the mask pattern for interference P1 appear periodically in the direction of light traveling.

To produce Talbot interference, it is necessary that at least the 0th-order light and the ±1st-order light be generated from the light transmissive pattern features P12. The self-produced image IM is produced in positions where all the beams of diffracted light are in the same phase. Here, the self-produced image IM refers to a produced image in which a light intensity distribution corresponding to the light transmissive pattern feature P12 appears. The reversed image IMr refers to a produced image in which a light intensity distribution corresponding to the reversal of the light transmissive pattern feature P12 appears. The interference light produced by Talbot interference includes reversed images IMr and self-produced images IM.

The reversed image IMr and the self-produced image IM appear alternately and periodically in the direction of light traveling in a direction away from the mask for interference M1 (the Z-direction). Here, the length of one period in the Z-direction for the self-produced image IM is the Talbot distance Z_{T}.

When the pitch p of the plurality of light transmissive pattern features P12 is near the wavelength of light λ, Z_{T} is expressed by Mathematical Formula 1.

$${z}_{T} = \frac{{p}^{2}}{λ} ( 1 + \sqrt{1 - {( \frac{λ}{p} )}^{2}} ) \qquad [ Mathematical Formula 1 ]$$

When the pitch p of the plurality of light transmissive pattern features P12 is twice or more the wavelength of light λ, Z_{T} is approximately expressed by Mathematical Formula 2.

$${z}_{T} \approx \frac{2 {p}^{2}}{λ} , p >> λ \qquad [ Mathematical Formula 2 ]$$

The pitch Pt in a direction orthogonal to the Z-direction of the self-produced image IM or the reversed image IMr satisfies Pt>λ/n, where n is the refractive index of the medium and λ is the wavelength of light.

In the emission of electrons shown in step S103, the interference light produced by Talbot interference is applied to a photoelectric conversion unit to cause the photoelectric conversion unit to emit electrons based on the interference light. The photoelectric conversion unit emits electrons therein excited by the applied light.

The interference light produced by Talbot interference (the light based on the interference pattern) is applied to the photoelectric conversion unit. Thus, the photoelectric conversion unit emits light from positions corresponding to the interference pattern formed by Talbot interference.

In the formation of a pattern shown in step S104, the electrons emitted in step S103 are applied to a processing object and a pattern is formed on the processing object. The processing object is a photosensitive material (resist), for example. The pattern includes a pattern obtained by etching an underlayer (a semiconductor wafer, a semiconductor layer, etc.) using a pattern formed on a resist or a resist pattern as a mask.

In the pattern formation method according to the embodiment, the transfer of a defect included in the mask pattern for interference P1 is suppressed by Talbot interference. Since electrons are applied to the processing object based on the interference light produced by Talbot interference, a pattern in which the configuration of the interference pattern formed by Talbot interference is minified or magnified can be formed with good accuracy by controlling the trajectory of electrons. In other words, in the pattern formation method according to the embodiment, both the merit of exposure technology using Talbot interference and the merit of exposure technology using an electron beam can be obtained.

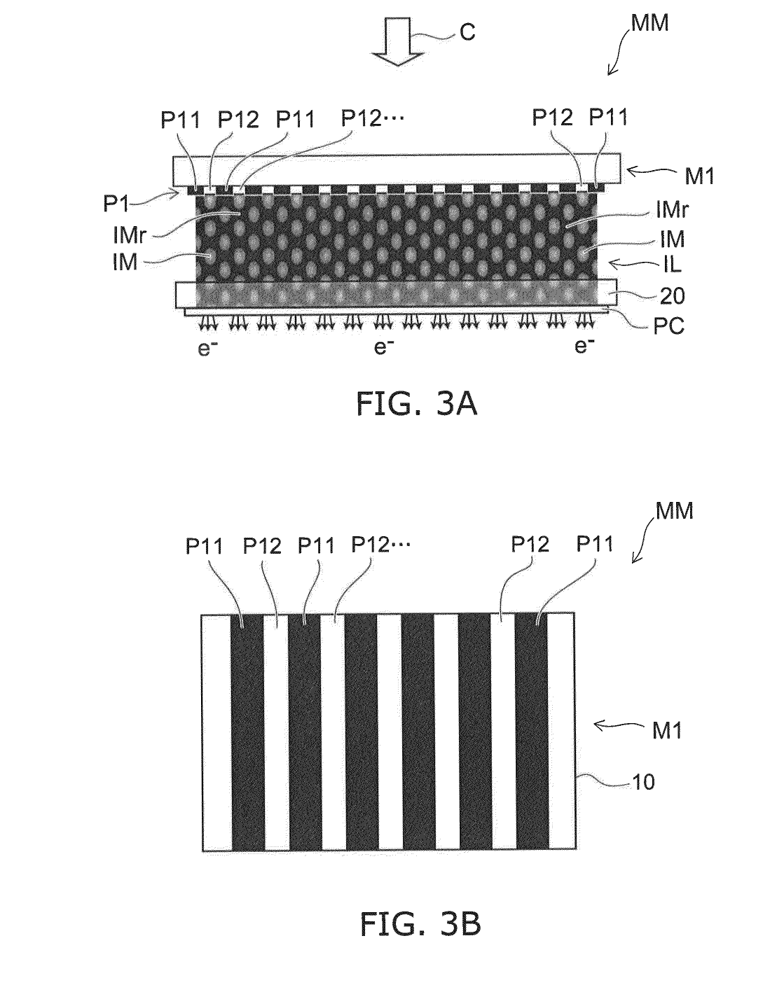

FIG. 3A and FIG. 3B are schematic views illustrating a mask for pattern formation.

FIG. 3A shows a schematic cross-sectional view of a mask for pattern formation MM. FIG. 3B shows a schematic plan view of the mask for pattern formation MM.

As shown in FIG. 3A, the mask for interference M1 and a photoelectric conversion unit PC are used for the mask for pattern formation MM. The photoelectric conversion unit PC is provided on one surface of a substrate 20. The photoelectric conversion unit PC is provided apart from the mask for interference M1. That is, a prescribed spacing is provided between the mask for interference M1 and the photoelectric conversion unit PC. As the material of the photoelectric conversion unit PC, a material in which an electron can be excited and emitted to the outside by light irradiation (e.g. metal such as gold (Au) and ruthenium (Ru)), alkali metal and group III-V composite semiconductor and so on are used. The photoelectric conversion unit PC may be provided integrally with or separately from the mask for interference M1.

As shown in FIG. 3B, a plurality of light blocking pattern features P11 and a plurality of light transmissive pattern features P12 formed in a line configuration are provided in the mask for interference M1 of the mask for pattern formation MM. In the example shown in FIG. 3B, the plurality of light blocking pattern features P11 and the plurality of light transmissive pattern features P12 constitute a line-and-space pattern (an L/S pattern). In the mask for interference M1, the plurality of light blocking pattern features P11 and the plurality of light transmissive pattern features P12 may constitute an island-like pattern or more complicated shape.

As shown in FIG. 3A, when light C is applied to the mask for pattern formation MM, interference light IL produced by Talbot interference is generated between the mask for interference M1 and the photoelectric conversion unit PC. Depending on the distance between the mask for interference M1 and the photoelectric conversion unit PC, self-produced images IM or reversed images IMr out of the interference light IL produced by Talbot interference are applied to the photoelectric conversion unit PC. Here, even when a defect is included in the mask pattern for interference P1 of the mask for interference M1, the pattern of the defect is less likely to be included in the interference light IL due to the effect of Talbot interference.

When the interference light IL is applied to the photoelectric conversion unit PC, in the position irradiated with light, electrons in the photoelectric conversion unit PC are excited and electrons e⁻ are emitted. The pattern of the electrons e⁻ emitted from the photoelectric conversion unit PC corresponds to the pattern of the interference light IL applied to the photoelectric conversion unit PC. For example, in the case where light resulting from self-produced images IM is applied to the photoelectric conversion unit PC, electrons e⁻ are emitted with a pattern corresponding to the pattern of the self-produced images IM from the photoelectric conversion unit PC. In the case where light resulting from reversed images IMr is applied to the photoelectric conversion unit PC, electrons e⁻ are emitted with a pattern corresponding to the pattern of the reversed images IMr from the photoelectric conversion unit PC.

Since the pattern of the electrons e⁻ emitted from the mask for pattern formation MM corresponds to the pattern of the interference light IL produced by Talbot interference, the pattern of a defect included in the mask pattern for interference P1 is not reflected. Therefore, by applying the electrons e⁻ to a processing object, the transfer of a defect to the pattern to be processed is suppressed.

Since the interference light IL is applied simultaneously to a large area of the surface of the photoelectric conversion unit PC, electrons e⁻ are emitted two-dimensionally from the photoelectric conversion unit PC. Thus, exposure can be performed on a large area in a short time, not exposure of single stroke drawing using electrons e⁻.

The electrons e⁻ may be minified or magnified between the mask for pattern formation MM and the processing object. By minifying the electrons e⁻, a pattern smaller than the pattern size of the interference light IL produced by Talbot interference can be formed. On the other hand, by magnifying the electrons e⁻, a pattern larger than the pattern size of the interference light IL produced by Talbot interference can be formed.

By using the mask for pattern formation MM like this, a periodic pattern in which low roughness is achieved due to Talbot interference and the transfer of a defect is suppressed can be applied to the photoelectric conversion unit PC uniformly over a large area. Consequently, a pattern can be formed with uniform pattern accuracy, and the reduction in throughput can be suppressed by collective pattern formation in a large area.

The photoelectric conversion unit PC may be formed uniformly on the substrate 20, or may have a prescribed pattern configuration. The prescribed pattern configuration may be different from the configuration of the mask pattern for interference P1. Thereby, the pattern of the electrons e⁻ emitted from the photoelectric conversion unit PC becomes a configuration in which the configuration of the mask pattern for interference P1 and the configuration of the pattern of the photoelectric conversion unit PC are superposed.

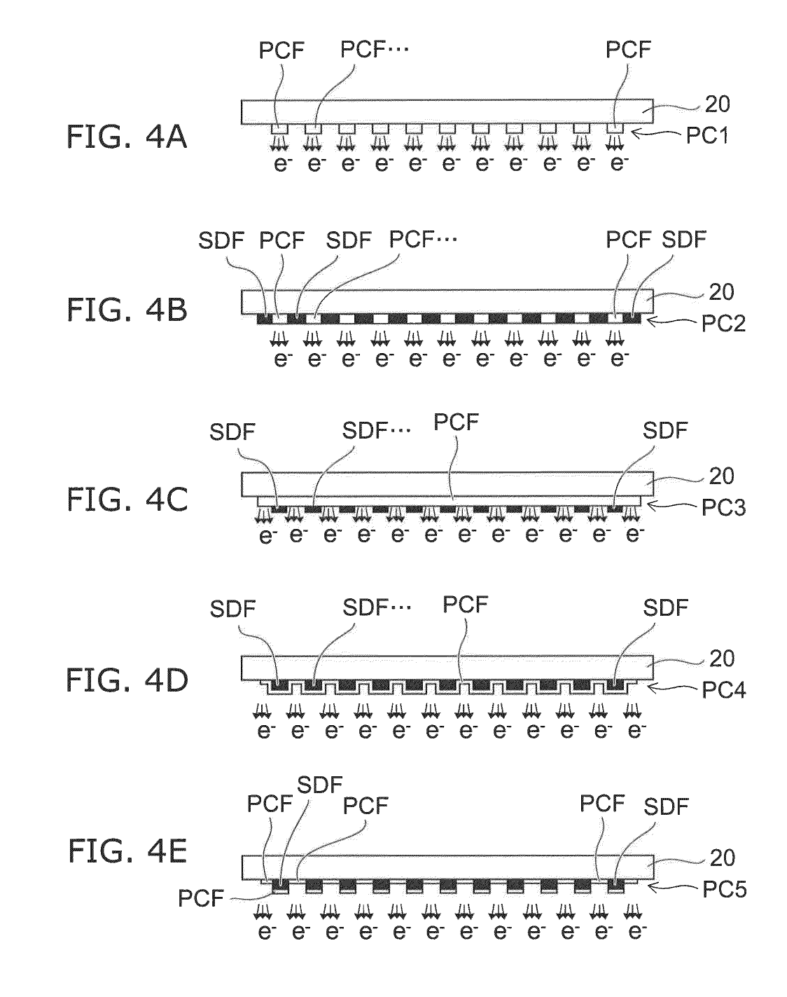

FIG. 4A to FIG. 4E are schematic cross-sectional views illustrating patterns of the photoelectric conversion unit.

The photoelectric conversion unit PC may be formed uniformly on the substrate 20, or may have a desired pattern configuration on one surface of the substrate 20 as shown in FIG. 4A to FIG. 4E.

A photoelectric conversion unit PC1 shown in FIG. 4A includes a plurality of photoelectric conversion films PCF provided on one surface of the substrate 20. The plurality of photoelectric conversion films PCF are provided to correspond to positions in the one surface of the substrate 20 where it is intended to emit electrons e⁻. In the photoelectric conversion unit PC1 thus configured, even if uniform light is applied to the photoelectric conversion unit PC1, electrons e⁻ are emitted with a pattern matched to the plurality of photoelectric conversion films PCF.

A photoelectric conversion unit PC2 shown in FIG. 4B includes a plurality of photoelectric conversion films PCF provided on one surface of the substrate 20 and a shield film SDF provided between photoelectric conversion films PCF. In the photoelectric conversion unit PC2 thus configured, even when there is a gap between photoelectric conversion films PCF, light can be blocked by the shield film SDF.

A photoelectric conversion unit PC3 shown in FIG. 4C includes a uniform photoelectric conversion film PCF provided on one surface of the substrate 20 and a plurality of shield films SDF formed on the photoelectric conversion film PCF.

A photoelectric conversion unit PC4 shown in FIG. 4D includes a plurality of shield films SDF provided on one surface of the substrate 20 and a photoelectric conversion film PCF covering the plurality of shield films SDF. The photoelectric conversion film PCF covers the upper side and the side surfaces of the plurality of shield films SDF and portions of the one surface of the substrate 20 where the shield film SDF is not provided. The photoelectric conversion film PCF is formed by forming the plurality of shield films SDF on the substrate 20 and then performing deposition, for example. In the photoelectric conversion unit PC4 thus configured, the photoelectric conversion film PCF provided on the shield film SDF is not irradiated with light, and the photoelectric conversion film PCF provided between shield films SDF is irradiated with light. Electrons e⁻ are emitted from the position of the photoelectric conversion film PCF irradiated with light.

A photoelectric conversion unit PC5 shown in FIG. 4E includes a plurality of shield films SDF provided on one surface of the substrate 20 and a photoelectric conversion film PCF provided on the plurality of shield films SDF and between shield films SDF. The photoelectric conversion film PCF covers the upper side of the plurality of shield films SDF and portions of the one surface of the substrate 20 where the shield film SDF is not provided. In the photoelectric conversion unit PC5 thus configured, the photoelectric conversion film PCF provided on the shield film SDF is not irradiated with light, and the photoelectric conversion film PCF provided between shield films SDF is irradiated with light. Electrons e⁻ are emitted from the position of the photoelectric conversion film PCF irradiated with light.

The configurations of the photoelectric conversion units PC1 to PC5 shown in FIG. 4A to FIG. 4E are only examples, and pattern configurations other than these are possible.

### Second Embodiment

Next, a pattern formation apparatus according to a second embodiment is described.

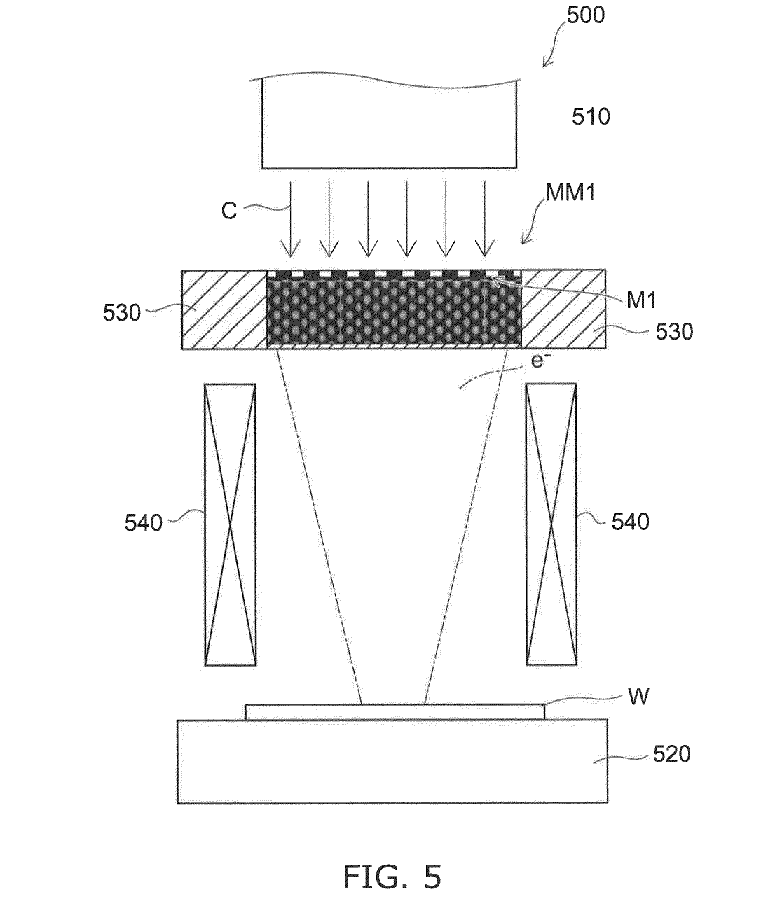

FIG. 5 is a schematic view illustrating a pattern formation apparatus.

As shown in FIG. 5, a pattern formation apparatus 500 according to the embodiment includes a light source 510, a stage 520, a mask holding unit 530, and an electron optics system 540.

The light source 510 emits light C used for exposure. The light source 510 emits, for example, laser light as the light C. The laser light is ArF excimer laser light of a wavelength of 193 nanometers (nm), for example.

The stage 520 holds a processing object thereon. In the example shown in FIG. 5, a wafer W is mounted as the processing object. The stage 520 attracts and holds the wafer W on the stage 520 by electrostatic attraction, for example. The stage 520 is provided movably along, for example, two axes (the X-axis and the Y-axis) along the surface of the wafer W. By moving the stage 520, the relative positional relationship between the wafer W and a mask for pattern formation held by the mask holding unit 530 described below is changed.

The mask holding unit 530 holds the mask for pattern formation MM including the mask for interference M1 and the photoelectric conversion unit PC. The mask holding unit 530 may be provided movably.

The electron optic system 540 converges the electrons e⁻ emitted from the photoelectric conversion unit PC of the mask for pattern formation MM. The electron optics system 540 converges, on the wafer W, the pattern of the electrons e⁻ in a two-dimensional form emitted from the photoelectric conversion unit PC.

When the total size of the regions in the photoelectric conversion unit PC where the pattern of electrons e⁻ is emitted is denoted by A1 and the transfer area on the wafer W is denoted by A2, the electron optics system 540 has a minification of A2/A1, for example. As an example, when the minification is set to 1/10 and A1 is set to 5 millimeters square (mm□), A2 is 500 micrometers square (μm□). Thus, electrons e⁻ can be collectively applied to the region of 500 μm□ on the wafer W, and the throughput of pattern formation is improved as compared to the case where an electron beam is applied by single stroke drawing.

In the pattern formation apparatus 500, by applying pattern light with very good image quality due to the Talbot effect to the photoelectric conversion unit PC, a periodic pattern such as an L/S pattern, a contact hole array and an array of more complicated shape can be converted to a pattern of electrons e⁻, and can be minified and transferred, for example.

In the mask for pattern formation MM, the distance between the mask for interference M1 and the photoelectric conversion unit PC is set based on the Talbot distance Z_{T}. For example, the spacing between the mask pattern for interference P1 and the photoelectric conversion unit PC is n times of ½ of the Talbot distance Z_{T} (n being a natural number). Thereby, light of reversed images IMr or self-produced images IM out of the interference light IL produced by Talbot interference is applied to the photoelectric conversion unit PC.

In this case, when an L/S pattern of 100 nanometers (nm), for example, is formed as the light blocking pattern features P11 of the mask pattern for interference P1, even when there is an LER (line edge roughness) of several nanometers, there is no such a roughness in the pattern of the interference light IL applied to the photoelectric conversion unit PC. Even when there is a defect pattern of several tens of nanometers in the mask pattern for interference P1, a good L/S pattern with no such a defect is applied to the photoelectric conversion unit PC. In this case, when the minification of the electron optics system 540 is set to 1/10, exposure of an L/S pattern of 10 nm can be collectively performed on the wafer.

### Third Embodiment

Next, pattern formation methods according to a third embodiment are described.

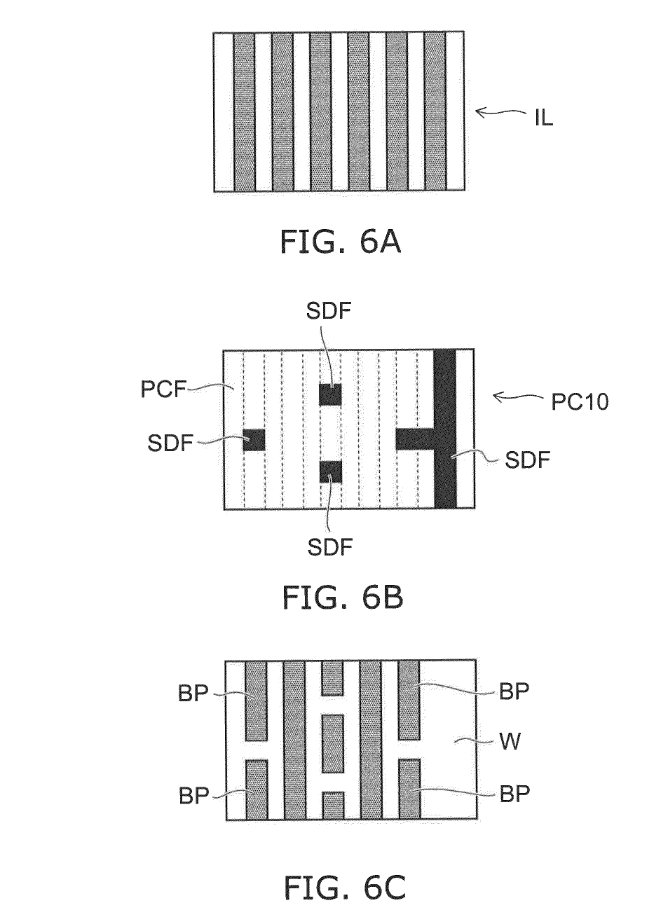

FIG. 6A to FIG. 6C are schematic views illustrating a pattern formation method according to the third embodiment.

FIG. 6A illustrates a pattern of interference light IL produced by Talbot interference. The interference light IL is formed by the mask for interference M1. In the example shown in FIG. 6A, interference light IL of an L/S pattern is formed.

In the embodiment, such interference light IL is applied to a photoelectric conversion unit PC10 shown in FIG. 6B. The photoelectric conversion unit PC10 photoelectrically converts part of the interference light IL. The photoelectric conversion unit PC10 includes a photoelectric conversion film PCF and a shield film SDF. The interference light IL applied to the portion of the shield film SDF is not photoelectrically converted. Consequently, the interference light IL is photoelectrically converted in the photoelectric conversion film PCF, which is the portion other than the shield film SDF.

FIG. 6C shows a pattern of electrons BP applied onto, for example, a wafer W that is a processing object. The pattern of electrons BP has a configuration in which the pattern of the interference light IL and the pattern of the photoelectric conversion film PCF, which is the portion other than the shield film SDF of the photoelectric conversion unit PC10, are superposed.

In the pattern formation method according to the embodiment, by blocking part of the periodic interference light IL produced by Talbot interference with the shield film SDF of the photoelectric conversion unit PC10, a pattern of electrons BP of a non-periodic pattern configuration can be formed. Thereby, a non-periodic pattern can be collectively formed on the wafer W, while exposure using Talbot interference and exposure using an electron beam are utilized.

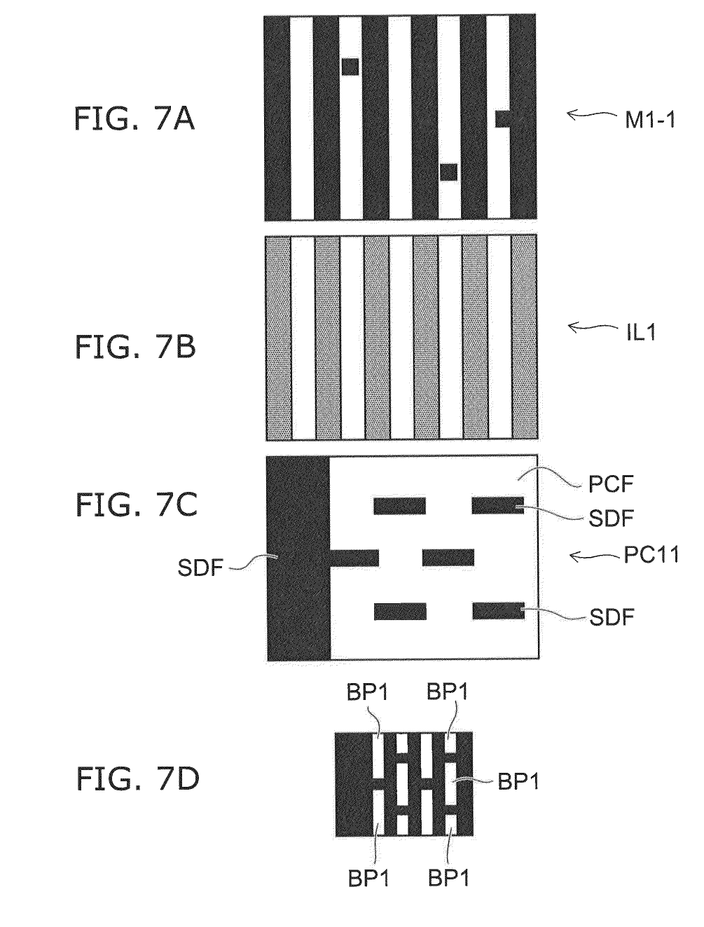

FIG. 7A to FIG. 9D are schematic views illustrating methods for forming a pattern of electrons.

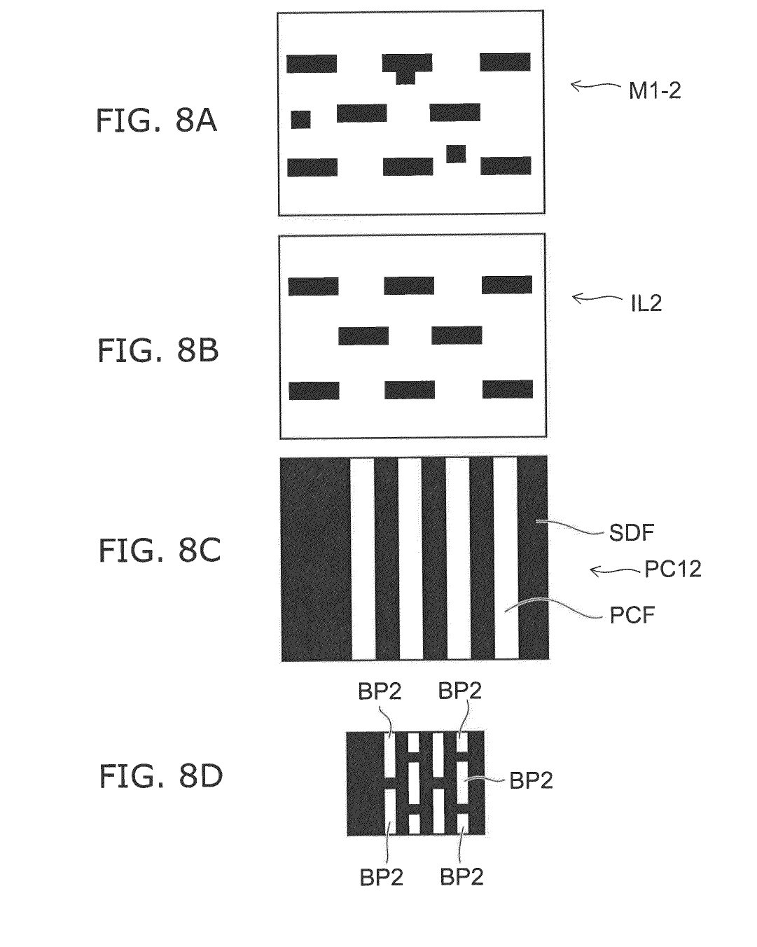

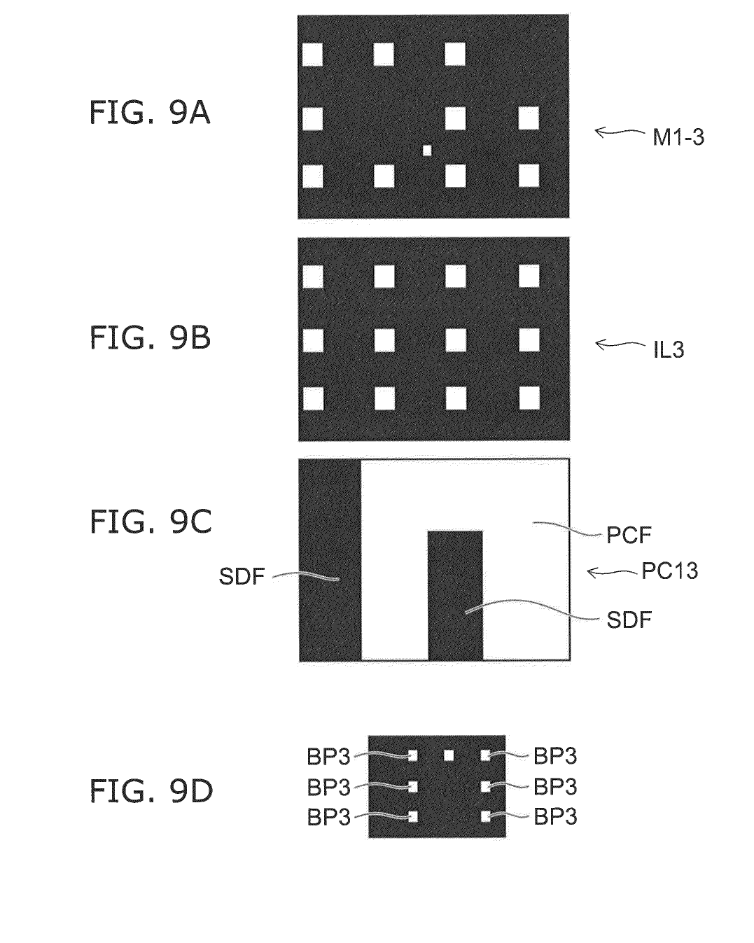

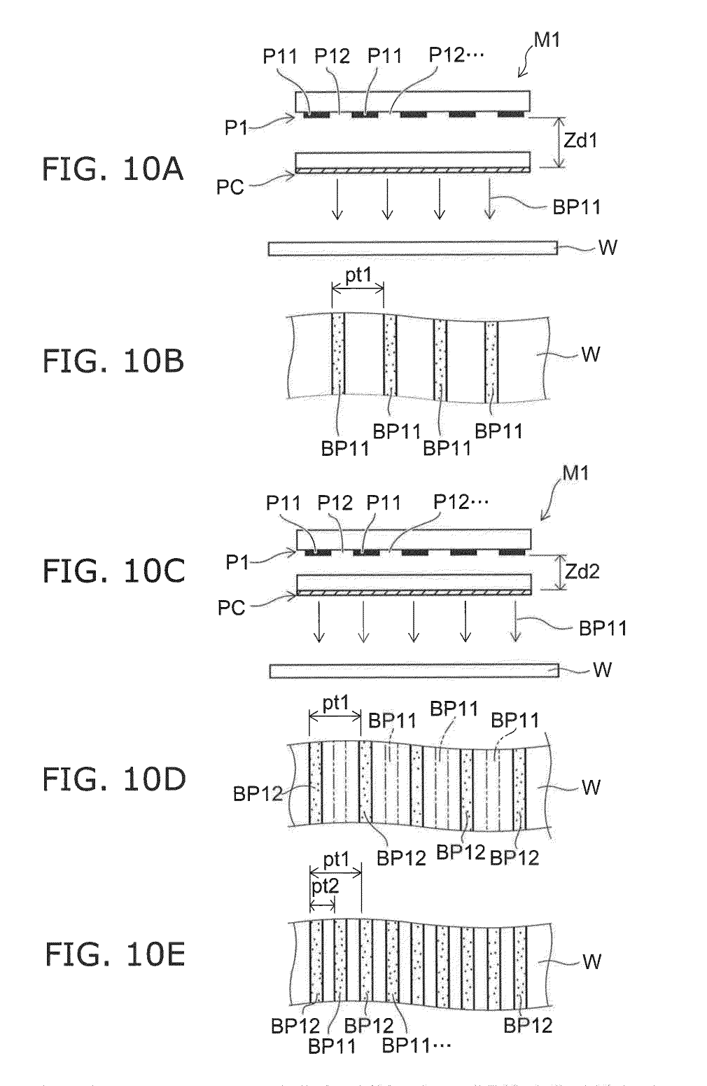

FIG. 7A to FIG. 7D show a first example, FIG. 8A to FIG. 8D show a second example, and FIG. 9A to FIG. 9D show a third example.

First, the first example is described.

FIG. 7A shows a partial region of a mask for interference M1-1. The mask for interference M1-1 has light blocking pattern features P11 and light transmissive pattern features P12 in a periodic line configuration. Defects DF are included in light transmissive pattern features P12 of the mask for interference M1-1

FIG. 7B shows part of interference light IL1 produced by Talbot interference. In the interference light IL1 produced by Talbot interference, the image of the defect DF shown in FIG. 7A is suppressed.

FIG. 7C shows part of a pattern of a photoelectric conversion unit PC11. The photoelectric conversion unit PC11 includes a photoelectric conversion film PCF and a shield film SDF. The shield film SDF blocks part of the interference light IL1 of Talbot interference formed by the mask for interference M1-1.

FIG. 7D shows part of a pattern of electrons BP1 applied onto a processing object. The pattern of electrons BP1 shown in FIG. 7D is formed by the superposition of the pattern of the interference light IL1 produced by Talbot interference shown in FIG. 7B and the pattern of the photoelectric conversion film PCF, which is the portion other than the shield film SDF of the photoelectric conversion unit PC11 shown in FIG. 7C. In the example shown in FIG. 7D, a pattern of electrons BP1 minified by the electron optics system 540 is shown.

Next, the second example is described.

FIG. 8A shows a mask for interference M1-2. The mask for interference M1-2 has a light transmissive pattern feature P12 and island-like light blocking pattern features P11 arranged in the light transmissive pattern feature P12. Defects DF are included in the light transmissive pattern feature P12 of the mask for interference M1-2.

FIG. 8B shows interference light IL2 produced by Talbot interference. In the interference light IL2 produced by Talbot interference, the image of the defect DF shown in FIG. 8A is suppressed.

FIG. 8C shows a pattern of a photoelectric conversion unit PC12. The photoelectric conversion unit PC12 includes a photoelectric conversion film PCF and a shield film SDF. The shield film SDF blocks part of the interference light IL2 of Talbot interference formed by the mask for interference M1-2.

FIG. 8D shows a pattern of electrons BP2 applied onto a processing object. The pattern of electrons BP2 shown in FIG. 8D is formed by the superposition of the pattern of the interference light IL2 produced by Talbot interference shown in FIG. 8B and the pattern of the photoelectric conversion film PCF, which is the portion other than the shield film SDF of the photoelectric conversion unit PC12 shown in FIG. 8C. In the example shown in FIG. 8D, a pattern of electrons BP2 minified by the electron optics system 540 is shown.

The pattern of electrons BP1 shown in FIG. 7D is the same as the pattern of electrons BP2 shown in FIG. 8D. In regard to which of the first example and the second example is to be used, an example out of the masks for interference M1-1 and M1-2 may be selected whereby the correction of the defect DF can be made easily. Also an example out of the photoelectric conversion units PC11 and PC12 may be selected whereby the shield film SDF can be formed with good accuracy.

Next, the third example is described.

FIG. 9A shows a mask for interference M1-3. The mask for interference M1-3 has a light blocking pattern feature P11 and island-like light transmissive pattern features P12 arranged in the light blocking pattern feature P11. A defect DF is included in the light blocking pattern feature P11 of the mask for interference M1-3.

FIG. 9B shows interference light IL3 produced by Talbot interference. In the interference light IL3 produced by Talbot interference, the image of the defect DF shown in FIG. 9A is suppressed.

FIG. 9C shows a pattern of a photoelectric conversion unit PC13. The photoelectric conversion unit PC13 includes a photoelectric conversion film PCF and a shield film SDF. The shield film SDF blocks part of the interference light IL3 of Talbot interference formed by the mask for interference M1-3.

FIG. 9D shows a pattern of electrons BP3 applied onto a processing object. The pattern of electrons BP3 shown in FIG. 9D is formed by the superposition of the pattern of the interference light IL3 produced by Talbot interference shown in FIG. 9B and the pattern of the photoelectric conversion film PCF, which is the portion other than the shield film SDF of the photoelectric conversion unit PC13 shown in FIG. 9C. In the example shown in FIG. 9D, a pattern of electrons BP3 minified by the electron optics system 540 is shown.

Other than the first to third examples described above, an arbitrary combination of the pattern configuration of the mask for interference M1 and the pattern configuration of the photoelectric conversion unit PC can be employed; thus, an arbitrary pattern of electrons can be set and applied onto a processing object.

### Fourth Embodiment

Next, a pattern formation method according to a fourth embodiment is described.

FIG. 10A to FIG. 10E are schematic views illustrating a pattern formation method according to the fourth embodiment.

In the embodiment, the process of forming a pattern (step S104 of FIG. 1) includes applying a first electron pattern to a processing object (e.g. a wafer W) and then applying a second electron pattern to the processing object.

FIG. 10A shows a first electron pattern BP11. The first electron pattern BP11 is a pattern of electrons generated in a state where the mask pattern for interference P1 of the mask for interference M1 and the photoelectric conversion unit PC are made apart from each other by a first distance Zd1.

FIG. 10B shows the first electron pattern BP11 applied onto, for example, a wafer W that is a processing object. In the example shown in FIG. 10B, the first electron pattern BP11 is a periodic pattern (e.g. an L/S pattern) having a first pitch pt1.

FIG. 10C shows a second electron pattern BP12. The second electron pattern BP12 is a pattern of electrons generated in a state where the mask pattern for interference P1 of the mask for interference M1 and the photoelectric conversion unit PC are made apart from each other by a second distance Zd2. Here, the absolute value of the difference between the first distance Zd1 and the second distance Zd2 is an odd multiple of ½ of the Talbot distance Z_{T}.

FIG. 10D shows the second electron pattern BP12 applied onto, for example, the wafer W that is a processing object. In the example shown in FIG. 10D, the second electron pattern BP12 is a periodic pattern (e.g. an L/S pattern) that has the first pitch pt1 equal to that of the first electron pattern BP11 and of which the phase is shifted by half the first pitch pt1. In other words, by shifting the second distance Zd2 by an odd multiple of ½ of the Talbot distance Z_{T} with respect to the first distance Zd1, the second electron pattern BP12 becomes a pattern in which the light and dark of the first electron pattern BP11 are reversed.

FIG. 10E shows a pattern of electrons applied onto, for example, the wafer W that is a processing object. In the embodiment, the pattern of electrons applied onto the wafer W is the first electron pattern BP11 and the second electron pattern BP12. Thereby, electrons of a periodic pattern (e.g. an L/S pattern) having a second pitch pt2 that is half the first pitch pt1 are applied onto the wafer W.

By such a pattern formation method according to the embodiment, a pattern of a pitch half that of the mask pattern for interference P1 can be formed on a processing object.

In the case where a mask pattern for interference P1 of an L/S pattern is minified to 1/10 and a pattern of 10 nm is formed on a wafer W, the pattern formation method according to the first embodiment needs to use a mask pattern for interference P1 with a half pitch (HP) of the L/S pattern of 100 nm, for example. When the embodiment is used, a mask pattern for interference P1 having an L/S pattern with an HP of 200 nm may be used. Thereby, the time and costs necessary to fabricate the mask for interference M1 are reduced. A fine pattern can be formed at lower cost.

Furthermore, in the embodiment, the number of electrons incident on the electron optics system at one time can be reduced by half. Accordingly, the resolution of the electron beam as photoelectron exposure is improved. This is because when electrons exist in a large number, repulsion due to the Coulomb force occurs between electrons in the beam is expanded. This is called the space charge effect. The space charge effect can be reduced when electrons are few, that is, the current is small. Thereby, a fine pattern in which the resolution is further increased can be formed at low cost.

Although the mask pattern for interference P1 described above is an L/S pattern, the mask pattern for interference P1 is not limited to L/S patterns, and any pattern other than L/S patterns is possible to the extent that it is a periodic pattern with an equal pitch.

### Fifth Embodiment

Next, masks for pattern formation according to a fifth embodiment are described.

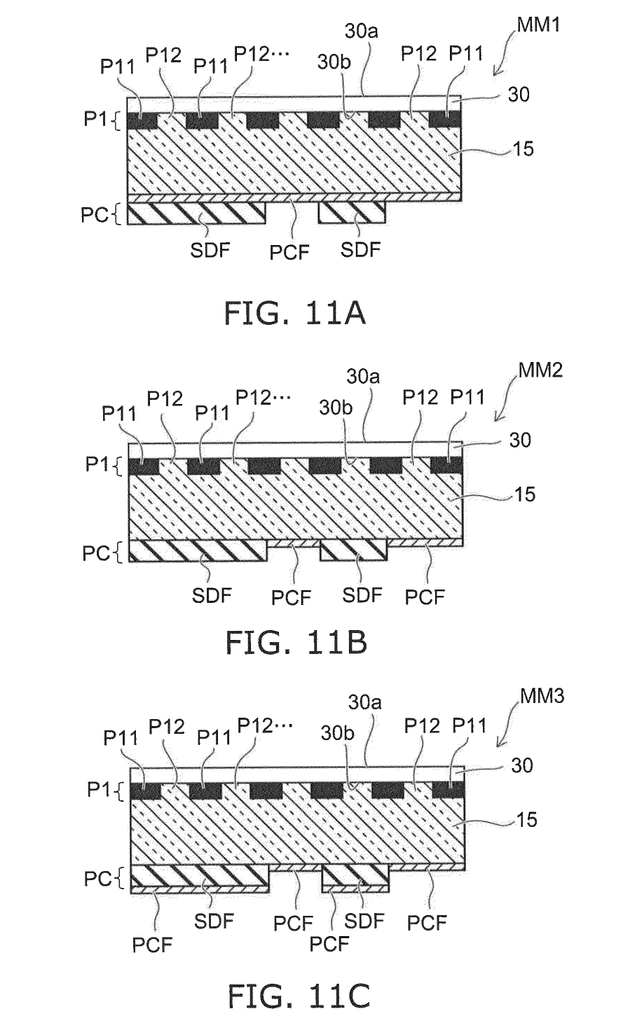

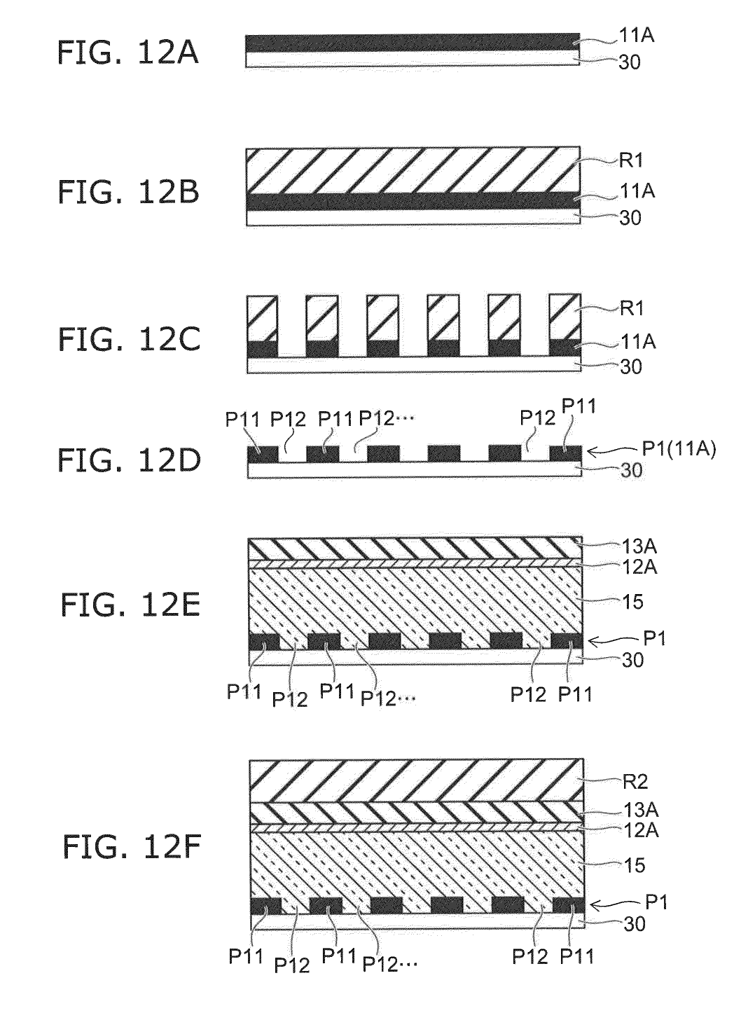

FIG. 11A to FIG. 11C are schematic cross-sectional views illustrating masks for pattern formation.

FIG. 11A shows a mask for pattern formation MM1, FIG. 11B shows a mask for pattern formation MM2, and FIG. 11C shows a mask for pattern formation MM3.

The mask for pattern formation MM1 shown in FIG. 11A includes a substrate 30, the mask pattern for interference P1, the photoelectric conversion unit PC, and an intermediate film 15. The substrate 30 has a first surface 30a and a second surface 30b on the opposite side to the first surface 30a. The substrate 30 transmits light of a prescribed wavelength. Quartz or synthetic quartz is used for the substrate 30, for example.

The mask pattern for interference P1 is provided on the second surface 30b of the substrate 30. The mask pattern for interference P1 generates interference light produced by Talbot interference. The mask pattern for interference P1 has a plurality of light blocking pattern features P11 and a plurality of light transmissive pattern features P12. The light blocking pattern feature P11 blocks the light mentioned above. The light transmissive pattern feature P12 transmits the light mentioned above.

The plurality of light blocking pattern features P11 are arranged on the substrate 30 with a prescribed width and a prescribed interval. The plurality of light transmissive pattern features P12 are each provided between light blocking pattern features P11. Thereby, the plurality of light transmissive pattern features P12 are provided periodically on the substrate 30.

The plurality of light blocking pattern features P11 and the plurality of light transmissive pattern feature P12 constitute an L/S pattern, for example. The plurality of light blocking pattern features P11 and the plurality of light transmissive pattern features P12 may constitute an island-like pattern. Cr, chromium oxynitride (CrON), and a stacked film of these are used as the light blocking pattern feature P11, for example.

The photoelectric conversion unit PC is provided apart from the mask pattern for interference P1. The photoelectric conversion unit PC emits electrons based on the interference light produced by Talbot interference formed by the mask pattern for interference P1. The photoelectric conversion unit PC includes a photoelectric conversion film PCF and a shield film SDF. Au and Ru are used for the photoelectric conversion film PCF, for example. Titanium nitride (TiN), Cr, tantalum (Ta), and a compound of these, and a stacked film of these are used for the shield film SDF, for example.

The intermediate film 15 is provided between the mask pattern for interference P1 and the photoelectric conversion unit PC. The intermediate film 15 transmits light of a prescribed wavelength similarly to the substrate 30. Silicon oxide (SiO₂) is used for the intermediate film 15, for example.

The photoelectric conversion film PCF is formed uniformly on a surface of the intermediate film 15 on the opposite side to the substrate 30. The shield film SDF is provided selectively on part of the photoelectric conversion film PCF.

The mask for pattern formation MM2 shown in FIG. 11B includes the substrate 30, the mask pattern for interference P1, the photoelectric conversion unit PC, and the intermediate film 15. The mask for pattern formation MM2 is different from the mask for pattern formation MM1 in the configuration of the photoelectric conversion unit PC. Otherwise, the configuration is similar to that of the mask for pattern formation MM1.

The photoelectric conversion unit PC of the mask for pattern formation MM2 includes a plurality of photoelectric conversion films PCF provided selectively on a surface of the intermediate film 15 on the opposite side to the substrate 30 and a shield film SDF provided between photoelectric conversion films PCF.

The mask for pattern formation MM3 shown in FIG. 11C includes the substrate 30, the mask pattern for interference P1, the photoelectric conversion unit PC, and the intermediate film 15. The mask for pattern formation MM3 is different from the mask for pattern formation MM1 in the configuration of the photoelectric conversion unit PC. Otherwise, the configuration is similar to that of the mask for pattern formation MM1.

The photoelectric conversion unit PC of the mask for pattern formation MM3 includes a plurality of shield films SDF provided selectively on a surface of the intermediate film 15 on the opposite side to the substrate 30 and a photoelectric conversion film PCF provided on the plurality of shield films SDF and between shield films SDF.

In all of the masks for pattern formation MM1 to MM3, the spacing between the mask pattern for interference P1 and the photoelectric conversion unit PC is defined by the thickness of the intermediate film 15. In the masks for pattern formation MM1 to MM3 that generate interference light produced by Talbot interference, it is necessary to dispose the mask pattern for interference P1 and the photoelectric conversion unit PC parallel with good accuracy. For example, if the period of Talbot interference is as short as several hundred nanometers, there is a possibility that due to a slight degradation in the degree of parallel, a uniform interference pattern in the exposure region cannot be applied to the photoelectric conversion unit PC. In particular, it is very difficult to keep two surfaces having a large area of approximately several millimeters square parallel at a certain distance.

Thus, like the masks for pattern formation MM1 to MM3, the mask pattern for interference P1 and the photoelectric conversion unit PC are configured integrally via the intermediate film 15. Thereby, even in the case of masks for pattern formation MM1 to MM3 with a large area, the mask pattern for interference P1 and the photoelectric conversion unit PC can be kept parallel with good accuracy.

In embodiments, although the intermediate film 15 is provided between the mask pattern for interference P1 and the photoelectric conversion unit PC in the masks for pattern formation MM1 to MM3 as an example, the intermediate film 15 may not be provided between these. In this case, other than the intermediate film 15, a support member (not shown) that can keep the spacing between the mask pattern for interference P1 and the photoelectric conversion unit PC with good accuracy may be used.

### Sixth Embodiment

Next, methods for manufacturing a mask for pattern formation according to a sixth embodiment are described.

FIG. 12A to FIG. 17D are schematic cross-sectional views illustrating methods for manufacturing a mask for pattern formation.

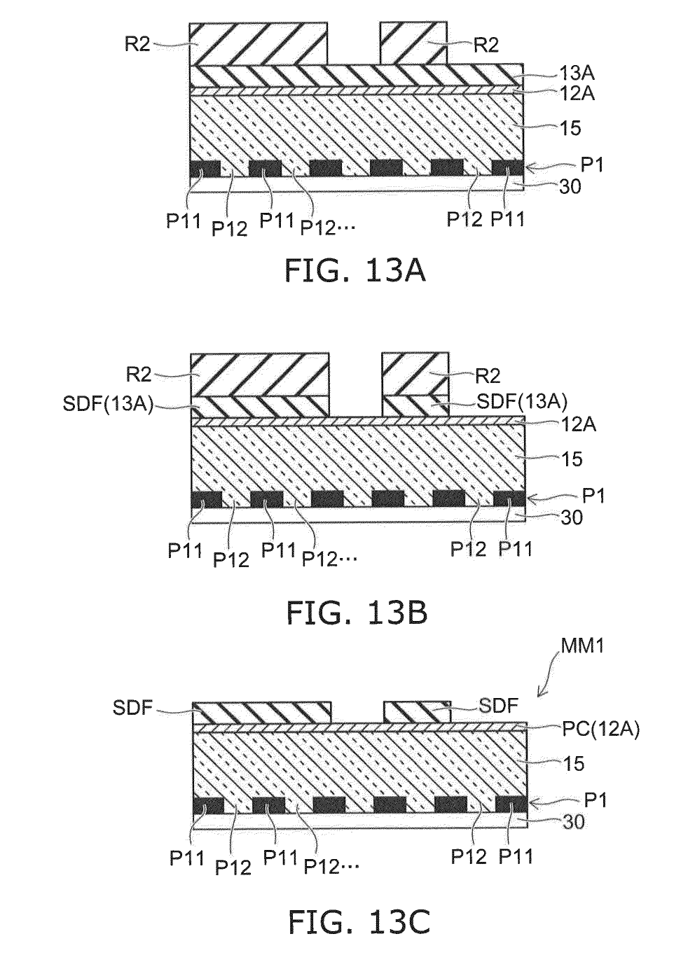

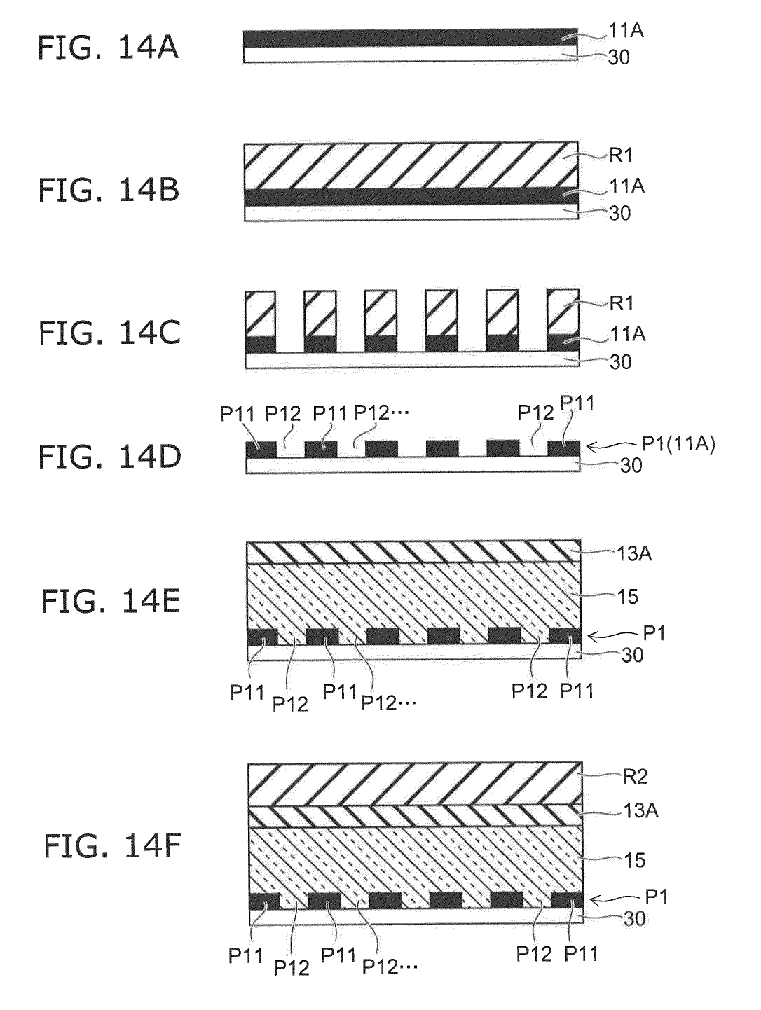

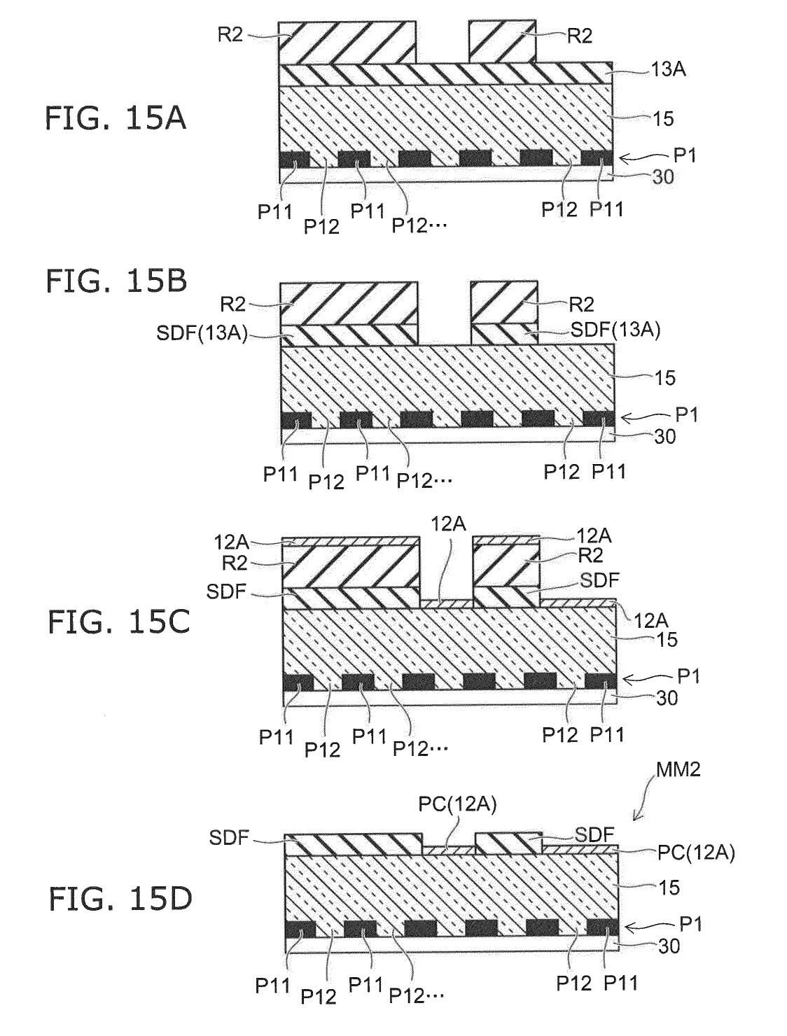

FIG. 12A to FIG. 13C illustrate a method for manufacturing the mask for pattern formation MM1 shown in FIG. 11A,

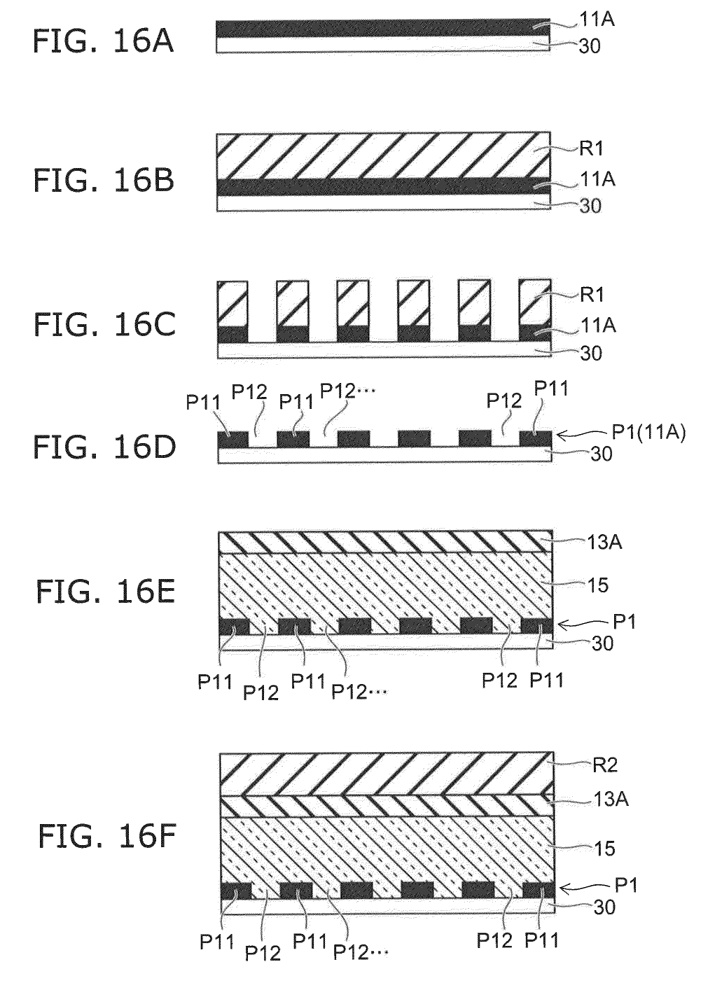

FIG. 14A to FIG. 15D illustrate a method for manufacturing the mask for pattern formation MM2 shown in FIG. 11B.

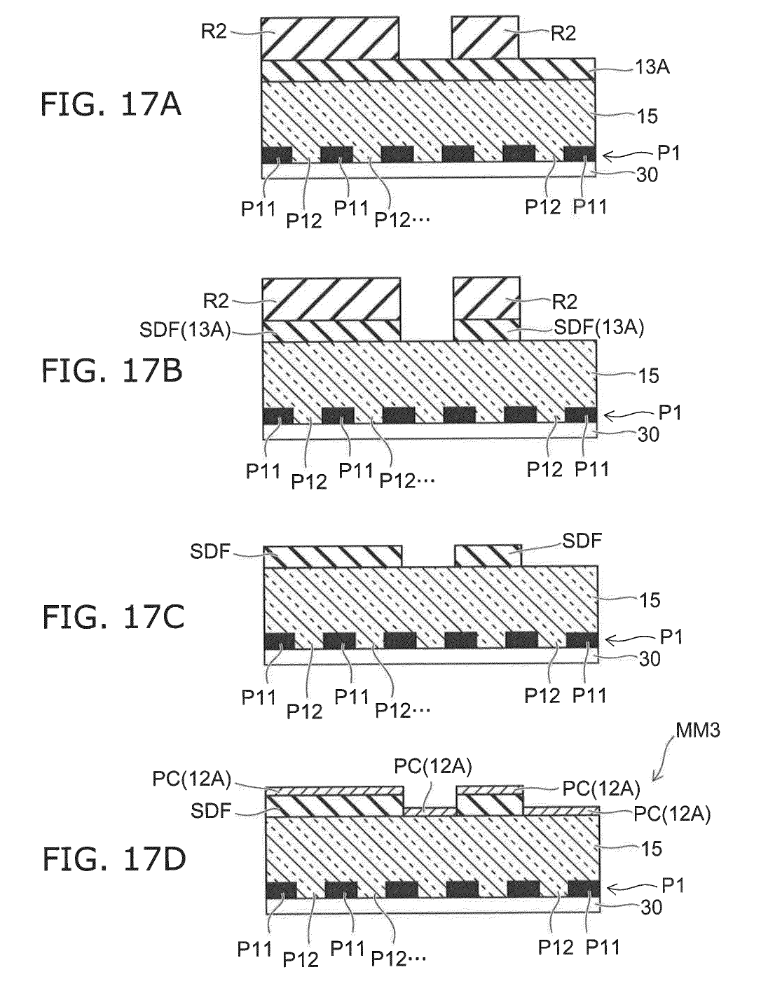

FIG. 16A to FIG. 17D illustrate a method for manufacturing the mask for pattern formation MM3 shown in FIG. 11C.

First, the method for manufacturing the mask for pattern formation MM1 is described based on FIG. 12A to FIG. 13C.

As shown in FIG. 12A, a shield film material 11A is deposited on the substrate 30 having light transmissivity. Synthetic quartz is used for the substrate 30, for example. A stacked film of Cr and CrON is used as the shield film material 11A.

Next, as shown in FIG. 12B, a resist film R1 is applied onto the shield film material 11A. After that, as shown in FIG. 12C, the resist film R1 is exposed and developed. Then, the patterned resist film R1 is used as a mask to perform etching processing on the shield film material 11A. After that, the resist film R1 is removed. Thereby, as shown in FIG. 12D, a plurality of light blocking pattern features P11 are formed on the substrate 30. The portions between light blocking pattern features P11 are a plurality of light transmissive pattern features P12.

Next, as shown in FIG. 12E, the intermediate film 15 is deposited on the light blocking pattern feature P11. SiO₂ is used for the intermediate film 15, for example. Then, a photoelectric conversion material film 12A is deposited on the intermediate film 15, and a shield film material 13A is deposited on the photoelectric conversion material film 12A. Au is used for the photoelectric conversion material film 12A, for example. A stacked film of Cr and CrON is used as the shield film material 13A.

Next, as shown in FIG. 12F, a resist film R2 is applied onto the shield film material 13A. After that, as shown in FIG. 13A, the resist film R2 is exposed and developed. Then, as shown in FIG. 13B, the patterned resist film R2 is used as a mask to perform etching processing on the shield film material 13A. After that, the resist film R2 is removed.

Thereby, as shown in FIG. 13C, a plurality of shield films SDF are formed on the photoelectric conversion material film 12A. The photoelectric conversion material film 12A is the photoelectric conversion unit PC. By such processes, the mask for pattern formation MM1 is completed.

Next, the method for manufacturing the mask for pattern formation MM2 is described based on FIG. 14A to FIG. 15D.

First, the processes shown in FIG. 14A to FIG. 14D are similar to the processes shown in FIG. 12A to FIG. 12D. Next, as shown in FIG. 14E, the intermediate film 15 is deposited on the light blocking pattern feature P11. SiO₂ is used for the intermediate film 15, for example. Then, the shield film material 13A is deposited on the intermediate film 15. A stacked film of Cr and CrON is used as the shield film material 13A.

Next, as shown in FIG. 14F, a resist film R3 is applied onto the shield film material 13A. After that, as shown in FIG. 15A, the resist film R3 is exposed and developed. Then, as shown in FIG. 15B, the patterned resist film R3 is used as a mask to perform etching processing on the shield film material 13A.

Next, as shown in FIG. 15C, the photoelectric conversion material film 12A is deposited on the resist film R3 and on the intermediate film 15 exposed by the previous etching. After that, the resist film R3 is removed. Thereby, only the photoelectric conversion material film 12A applied on the resist film R3 is removed, and the photoelectric conversion film PCF is formed between shield films SDF as shown in FIG. 15D. By such processes, the mask for pattern formation MM2 is completed.

Next, the method for manufacturing the mask for pattern formation MM3 is described based on FIG. 16A to FIG. 17D.

First, the processes shown in FIG. 16A to FIG. 17B are similar to the processes shown in FIG. 14A to FIG. 15B. Next, the resist film R3 is removed. Thereby, as shown in FIG. 17C, a plurality of shield films SDF are formed on the intermediate film 15.

Next, as shown in FIG. 17D, the photoelectric conversion material film 12A is formed on the plurality of shield films SDF and on the intermediate film 15 where the shield film SDF is not formed. The photoelectric conversion material film 12A is the photoelectric conversion unit PC. By such processes, the mask for pattern formation MM3 is completed.

By the methods for manufacturing the masks for pattern formation MM1 to MM3 according to the embodiment, the spacing between the mask pattern for interference P1 including the light blocking pattern feature P11 and the photoelectric conversion unit PC can be set with good accuracy by the thickness of the intermediate film 15.

As described above, the pattern formation method, the mask for pattern formation, and the pattern formation apparatus according to the embodiment can form a high accuracy pattern in a large area in a short time.

Hereinabove, embodiments and modification examples thereof are described. However, the invention is not limited to these examples. For example, one skilled in the art may appropriately make additions, removals, and design modifications of components to the embodiments or the modification examples described above, and may appropriately combine features of the embodiments; such modifications also are included in the scope of the invention to the extent that the spirit of the invention is included.

The pattern formation method, the mask for pattern formation, and the pattern formation apparatus according to the embodiment can be used not only for the formation of a fine pattern of a semiconductor device, but also for the fabrication of various devices, such as a MEMS (micro-electro-mechanical system), in which pattern formation using photolithography technology is performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A pattern formation method comprising:
preparing a mask pattern for interference, a photoelectric conversion unit, and a processing object, the mask pattern for interference being periodically arranged a plurality of light transmissive portions, the photoelectric conversion unit being disposed apart from the mask pattern for interference;
applying light to the mask pattern for interference to produce Talbot interference based on transmitted light of the light transmitted through the light transmissive portions;
applying interference light produced by the Talbot interference to the photoelectric conversion unit to cause the photoelectric conversion unit to emit electrons based on the interference light; and
forming a pattern by applying the electrons to the processing object.

2. The method according to claim 1, wherein the photoelectric conversion unit converts a part of the interference light to the electrons.

3. The method according to claim 1, wherein the forming a pattern includes forming a third pattern that is a configuration in which a first pattern formed on the photoelectric conversion unit of the interference light and a second pattern that is a configuration of the photoelectric conversion unit are superposed.

4. The method according to claim 1, further comprising an electron blocking unit configured to block a part of the electrons,
the forming a pattern including forming a third pattern being superposed a first pattern and a second pattern, the first pattern being formed on the photoelectric conversion unit of the interference light, the second pattern being a configuration of the electron blocking unit.

5. The method according to claim 1, wherein
the forming a pattern includes:
applying a first electron pattern to the processing object in a state where the mask pattern for interference and the photoelectric conversion unit are made apart from each other by a first distance; and
after that applying a second electron pattern to the processing object in a state where the mask pattern for interference and the photoelectric conversion unit are made apart from each other by a second distance, an absolute value of a difference between the first distance and the second distance being an odd multiple of ½ of a Talbot distance based on the Talbot interference.

6. The method according to claim 1, wherein the photoelectric conversion unit is one of Au, Ru, alkali metal and composite semiconductor.

7. A mask for pattern formation comprising:
a mask pattern for interference having a plurality of light transmissive portions arranged periodically, the mask pattern for interference being configured to generate interference light produced by Talbot interference; and
a photoelectric conversion unit provided apart from the mask pattern for interference and configured to emit electrons based on interference light produced by the Talbot interference.

8. The mask according to claim 7, further comprising an intermediate member provided between the mask pattern for interference and the photoelectric conversion unit, the intermediate member being configured to transmit the interference light.

9. The mask according to claim 7, further comprising an interference light blocking unit provided between the mask pattern for interference and the photoelectric conversion unit, the interference light blocking unit having a second pattern having a configuration different from a first pattern formed by the interference light, and the interference light blocking unit being configured to block a part of the interference light.

10. The mask according to claim 7, further comprising an electron blocking unit provided on the photoelectric conversion unit, the electron blocking unit having a second pattern having a configuration different from a first pattern formed by the interference light, and the electron blocking unit being configured to block a part of the electrons.

11. The mask according claim 7, wherein a spacing between the mask pattern for interference and the photoelectric conversion unit is n times of ½ of a Talbot distance based on the Talbot interference (n being a natural number).

12. The mask according to claim 7, wherein
the mask pattern for interference has a plurality of light blocking pattern features and
the plurality of light blocking pattern features are arranged with a prescribed width and a prescribed interval.

13. The mask according to claim 12, wherein each of the plurality of light blocking pattern features extends in one direction.

14. The mask according to claim 7, wherein the photoelectric conversion unit is one of Au, Ru, alkali metal and composite semiconductor.

15. A method for manufacturing a mask for pattern formation comprising;
forming a mask pattern for interference on a substrate configured to transmit light, the mask pattern for interference having a plurality of light transmissive portions arranged periodically and being configured to generate interference light produced by Talbot interference;
forming an intermediate member on the mask pattern for interference, the intermediate member being configured to transmit the interference light; and
forming a photoelectric conversion unit on the intermediate member, the photoelectric conversion unit being configured to emit electrons based on the interference light.

16. The method according to claim 15, further comprising forming an electron blocking unit on the photoelectric conversion unit, the electron blocking unit being configured to block a part of the electrons.

17. The method according to claim 15, further comprising forming an interference light blocking unit provided between the intermediate member and the photoelectric conversion unit.

18. A pattern formation apparatus comprising:
a light source configured to emit light;
a stage configured to hold a processing object thereon;
a mask holding unit configured to hold a mask for pattern formation, the mask for pattern formation including a mask pattern for interference and a photoelectric conversion unit, the mask pattern for interference being configured to generate interference light produced by Talbot interference, the photoelectric conversion unit being configured to emit electrons based on the interference light produced by the Talbot interference; and
an electron optics system configured to converge the electrons emitted from the photoelectric conversion unit.
